(19) United States
(12) Patent Application Publication
(10) Pub. No.: US 2026/0299435 A1
(43) Pub. Date: Oct. 1, 2026

(54) CONFIGURABLE ILLUMINATION SOURCE FOR OPTICAL METROLOGY AND RELATED METHODS

(71) Applicant: NOVA LTD., Rehovot (IL)

(72) Inventors: Eyal COHEN, Rehovot (IL); Slava MACHNOVSKY, Rehovot (IL); Alex DAVIDOVICH, Rehjovot (IL); Shimon YALOV, Rehovot (IL); Meir COHEN

(73) Assignee: NOVA LTD., Rehovot (IL)

(21) Appl. No.: 19/476,681

(22) PCT Filed: Apr. 18, 2024
(86) PCT No.: PCT/IB2024/053777

§ 371 Date: Oct. 17, 2025

Related U.S. Application Data
(60) Provisional application No. 63/496,946, filed on Apr. 18, 2023.

(51) Int. Cl. G03F 7/00

(52) U.S. Cl. CPC G03F 7/706849; G03F 7/706833

(57) ABSTRACT

The application pertains to an illumination source for optical metrology. The source includes a matrix that includes twenty-five light emitting diodes (LEDs) arranged in twelve sets associated with twelve peak wavelength ranges. The sets have peak wavelength ranges within the 400 till 1000 nanometer range. Each set of LEDs is controlled independently, and each LED has a controllable intensity. The illumination source also includes a controller configured to selectively activate any combination of LEDs and control the matrix based on a metrology recipe. The claim also includes a method for illuminating a sample using the illumination source.

### CROSS REFERENCE

This application claims priority from U.S. provisional patent Ser. No. 63/496,946 filing date Apr. 18, 2023 which is incorporated herein by reference.

### TECHNICAL FIELD

The invention pertains to the field of optical metrology, specifically to an illumination source comprising a matrix of light emitting diodes (LEDs) arranged in distinct sets associated with different peak wavelength ranges.

### BACKGROUND

Optical metrology is a critical field that involves the use of light to measure various properties of an object. This field has a wide range of applications, from the inspection of semiconductor wafers to the analysis of biological samples.

Optical Critical Dimension (OCD) is a metrology technique used in the semiconductor industry to measure and characterize the dimensions of features on a semiconductor wafer. It plays a crucial role in ensuring the quality and performance of integrated circuits.

OCD relies on the principles of optical scatterometry, which involves analyzing the light scattered from a patterned wafer surface to extract information about its dimensions. By measuring the intensity and phase of the scattered light, OCD can determine critical dimensions such as line widths, spaces, and heights with high precision and accuracy.

One of the key advantages of OCD is its non-destructive nature, allowing for in-line measurements during the semiconductor manufacturing process without the need for physical contact with the wafer. This enables real-time monitoring and control of critical dimensions, ensuring that the fabricated devices meet the required specifications.

OCD can provide valuable information about the dimensional variations across a wafer, as well as variations between different wafers in a batch. This data is essential for process optimization, yield improvement, and quality control. By detecting and quantifying deviations from the desired dimensions, OCD helps identify process variations and potential issues early on, allowing for corrective actions to be taken.

OCD is particularly valuable in advanced semiconductor manufacturing processes where the dimensions of features are becoming increasingly smaller and more challenging to measure using traditional techniques. As the industry continues to push the limits of miniaturization, OCD provides a critical tool for ensuring the quality and performance of nanoscale devices.

One of the key components in optical metrology systems is the illumination source, which provides the light that interacts with the sample being measured.

QTH lamps, also known as Quartz Tungsten Halogen lamps, are a type of incandescent lamp that is commonly used in various applications, including photography, microscopy, and industrial lighting. These lamps are known for their high color temperature, excellent color rendering, and long lifespan.

One of the key features of QTH lamps is their use of a tungsten filament enclosed in a quartz envelope. This design allows the lamp to operate at higher temperatures, resulting in a higher color temperature compared to standard incandescent lamps. The quartz envelope also provides better thermal stability and resistance to chemical reactions, making QTH lamps suitable for demanding environments.

QTH lamps emit a continuous spectrum of light, which is important in applications where accurate color reproduction is required, such as in photography and microscopy. The high color rendering index (CRI) of QTH lamps ensures that colors appear natural and vibrant, making them ideal for applications where color accuracy is crucial.

Quartz Tungsten Halogen (QTH) lamps, offer a broad spectrum of light, making them suitable for a variety of applications. However, these sources have certain limitations. These QTH lamps are broad band light sources and need to be followed by bandpass filters for selectively filtering out unwanted wavelengths and restrict the emission to a narrower range. However, these filters have a fixed filtering function. Therefore, there is a need for an improved illumination source that can provide a versatile and customizable light output for optical metrology applications.

### SUMMARY

In accordance with embodiments, an illumination source for use in optical metrology is provided. The illumination source includes a matrix that includes at least twenty-five light emitting diodes (LEDs) that are arranged in at least twelve different sets of LEDs associated with at least twelve peak wavelength ranges. Each LED of any of the set is controlled independently from any other LED of the matrix. The illumination source further includes a controller configured to selectively activate any combination of any LEDs of the matrix and to control the matrix based on a metrology recipe.

According to an embodiment, the matrix may include twenty-five or more than twenty-five LEDs. For example may include 6×6 LEDs, 7×7 LEDs, 8×8 LEDs, 6×5 LEDs, 5×7 LEDs, and the like.

According to an embodiment, the LEDs are arranged in a rectangular array, in a square array, or any other shape of array.

According to an embodiment, the number of sets exceeds twelve. 206

According to an embodiment, the matrix may include twenty-five or more than twenty-five LEDs. For example may include 36 LEDs, 48 LEDs, and the like

In accordance with other embodiments, a method for illuminating a sample is provided. The method involves illuminating a sample with radiation using an illumination source that includes a matrix that includes twenty-five light emitting diodes (LEDs) that are arranged in twelve different sets of LEDs associated with twelve peak wavelength ranges. Each LED of any of the set is managed separately from any other LED of the structured arrangement.

It has been found that the specific combination of wavelength ranges of the twelve sets of LEDs is highly suited for metrology of a large range of samples and structures.

### LIST OF FIGURES

FIG. 1 illustrates an example of a method;

FIG. 2 illustrates an example of an illumination source; and

FIG. 3 illustrates examples of images generated using different illumination schemes.

### DETAILED DESCRIPTION

According to an embodiment, there is provided an illumination source for use in optical metrology, the illumination source includes a matrix that includes twenty-five light emitting diodes (LEDs) that are arranged in twelve different sets of LEDs associated with twelve peak wavelength ranges, wherein (i) a first set and a second set have their peak wavelength range within the 400 till 500 nanometer range, (ii) a third set has its peak wavelength range within the 500 till 600 nanometer range, (iii) a fourth set has its peak wavelength range within the 600 till 700 nanometer range, (iv) wherein a fifth set, a sixth and a seventh set have their peak wavelength range within the 700 till 800 nanometer range, (v) an eighth set and a ninth set have their peak wavelength range within the 800 till 900 nanometer range, (vi) a tenth set, an eleventh set and a twelfth set have their peak wavelength range within the 900 till 1000 nanometer range.

According to an embodiment, the first set has its peak wavelength range within the 400-405 nanometer sub-range, the second set has its peak wavelength range within the 450-455 nanometer sub-range, the third set has its peak wavelength range within the 525-530 nanometer sub-range, the fourth set has its peak wavelength range within the 670-680 nanometer sub-range, the fifth set has its peak wavelength range within the 700-705 nanometer sub-range, and the sixth set has its peak wavelength range within the 725-750 nanometer sub-range.

According to an embodiment, the seventh set has its peak wavelength range within the 785-790 nanometer sub-range, the eighth set has its peak wavelength range within the 835-830 nanometer sub-range, the ninth set has its peak wavelength range within the 860-870 nanometer sub-range, the tenth set has its peak wavelength range within the 905-910 nanometer sub-range, the eleventh set has its peak wavelength range within the 940-950 nanometer sub-range, and the twelfth set has its peak wavelength range within the 985-990 nanometer sub-range.

According to an embodiment, each set of the third till eleventh sets consists of more LEDs than the first till fourth sets, and the twelfth set has a highest number of LEDs of any of the sets.

According to an embodiment, each set of the first till fourth sets consists of a single LED, each set of the fifth till tenth sets consist of a pair of LEDs, the eleventh set consists of three LEDs, and the twelfth set consists of six LEDs.

According to an embodiment, each LED of any of the set is controlled independently from any other LED of the matrix.

According to an embodiment, set is controlled independently from any other set of the matrix.

According to an embodiment, each LED of the matrix has a controllable intensity.

According to an embodiment, the illumination source includes a controller.

According to an embodiment, the controller is configured to selectively activate any combination of any LEDs of the matrix.

According to an embodiment, the controller is configured to select out of first plurality of red light illumination combinations, out of a second plurality of infrared illumination combinations and out of a third plurality of blue illumination combinations.

According to an embodiment, the controller is configured to control at least one of the sets to continuously illuminate a sample.

According to an embodiment, the controller is configured to control at least one of the sets to non-continuously illuminate a sample.

According to an embodiment, the controller is configured to control the matrix based on a metrology recipe.

According to an embodiment, the controller is configured to control the matrix to illuminate a sample with different combinations of LEDs during different illumination pulses.

There is provided an illumination source that can replace of currently used QTH lamp(s) with Filters Wheel used in Pattern Recognition and Auto-Focus (AF) module of Integrated metrology Tools.

The illumination source is cost effective. Some of the cost was reduced by replacing constantly working QTH lamps with LEDs that are closed most of the time and are activated during image grabbing, whereas the image grabbing duration is very short.

The illumination source is compact and can replace an existing QTH lamp illumination module.

The illumination source exhibits an improved performance (in comparison to the QTH illumination modules) based on advantageously using LEDs (for example—by adding/magnification wavelengths/ranges—e.g. IR, Blue, power consumption, etc.) for Pattern Recognition (PR).

The illumination source may emit radiation of different colors—for example red (IR) radiation as well as radiation of other colors.

The illumination source support pattern matching current and future challenges, allows maximum flexibility in minimum time, increases reliability level, have enough power to illuminate a sample with only one color, and exhibits a large dynamic range which allows a vast number of illumination configurations.

The illumination source may use a LEDs matrix that is capable of changing and/or mixing the emitted colors, whereas each LED or each set of LEDs is controlled independently.

At least one LED of the matrix may be a multicolor LED.

The versatility of the illumination source allows to support multiple metrology recipes and is a differentiator when it comes to pattern recognition challenges. The illumination source allows to generate a recipe with much more baseline combinations, with comparison to today's situation, when one should generate recipe for each layer.

The illumination can rapidly change, during evaluation of the sample, thereby providing rich information about the sample.

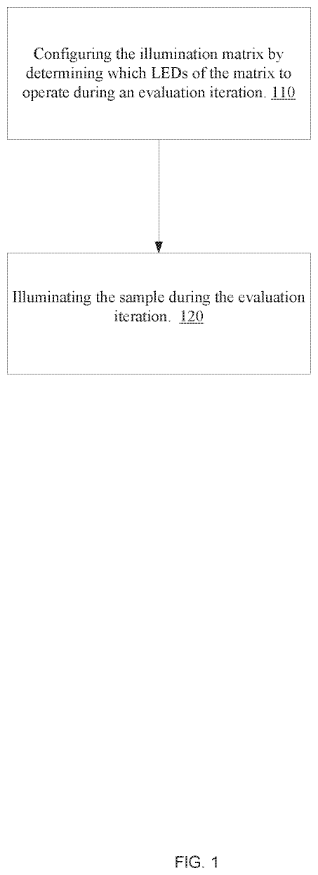

FIG. 1 illustrates an example of method 100.

According to an embodiment, method 100 includes step 110 of configuring the illumination matrix by determining which LEDs of the matrix to operate during an evaluation iteration, when to operate any of the LEDs of the matrix and at what intensity. Step 110 may be executed in a LED resolution or in a set of LEDs resolution.

According to an embodiment, step 110 is followed by step 120 of illuminating the sample during the evaluation iteration.

According to an embodiment, step 120 includes directing radiation from a matrix that includes twenty-five light emitting diodes (LEDs) onto a sample for measurement purposes. This matrix is organized into twelve sets, each corresponding to a designated range of wavelengths. The purpose of this configuration is to provide a light source that can be adjusted to meet the specific requirements of a metrology task.

The matrix allows for the independent control of each LED, enabling adjustments in the intensity and combination of wavelengths. A controller is responsible for activating any combination of LEDs and can be programmed to illuminate the sample in a continuous or non-continuous manner, based on predefined parameters or to change illumination during different pulses.

The matrix is designed to enable the independent management of each LED, which allows for fine-tuning of the light output to achieve the desired illumination profile. This feature is essential for obtaining accurate measurements in metrology, where the precision of feature characterization can depend on the specificity of the light source.

Steps 110 and 120 encompass the configuration and operation of a matrix designed for metrology, providing a customizable and precise illumination source capable of emitting light across a wide range of wavelengths with independently controllable intensity for each LED.

Step 120 involves the independent management of each LED within a structured arrangement. This step allows for the adjustment of the intensity, on/off state, and the duration of illumination for each LED. The purpose of this capability is to customize the light output to meet specific metrology task requirements. For instance, if a particular feature on a sample requires illumination with a certain wavelength and intensity, only the LEDs that correspond to that wavelength range can be activated at the desired intensity levels.

Method 100 involves using the matrix and a controller, and software executed by the controller for the illumination process. The controller executes the instructions, which dictate which LEDs should be active, their intensity levels, and the timing of their illumination. This enables the illumination source to create a variety of combinations of wavelength ranges and intensities, which is necessary for high-quality measurements where different materials and structures may require different lighting conditions.

The parameters set in step 110 include the electrical characteristics related to the operation of each LED, such as voltage and current, which are adjusted to determine the intensity of the emitted light. The controller is configured to modify these parameters for each LED without affecting the others. Additionally, the timing control is precise to ensure that the LEDs are activated and deactivated at the intended moments, particularly if the illumination is not continuous.

Accordingly, step 120 involves the independent adjustment of each LED (or of each set) in a matrix to provide specific illumination for metrology. This step is necessary for achieving the flexibility and control needed to accurately measure various samples under differing conditions.

Step 110 may benefit from having one or more sets that include more than a single LED, whereas the number of LEDs in each set influences the intensity and coverage of light that can be emitted, with a higher count allowing for more robust illumination capabilities within their respective wavelength ranges.

Each LED's intensity (or each set intensity) can be individually adjusted, allowing for precise control over the illumination pattern. This capability enables the adjustment of light output to meet the specifications of different metrology processes, which may require specific intensities and combinations of wavelengths for optimal measurement accuracy.

In practice, the steps are realized through the engineering and production of the LED matrix, the programming of the controller that manages the intensity and activation of each LED, and the incorporation of the illumination source into an optical metrology system. The controller's ability to selectively activate and modulate the LEDs enables the system to adapt to various measurement scenarios, providing a flexible and effective tool for the characterization of samples.

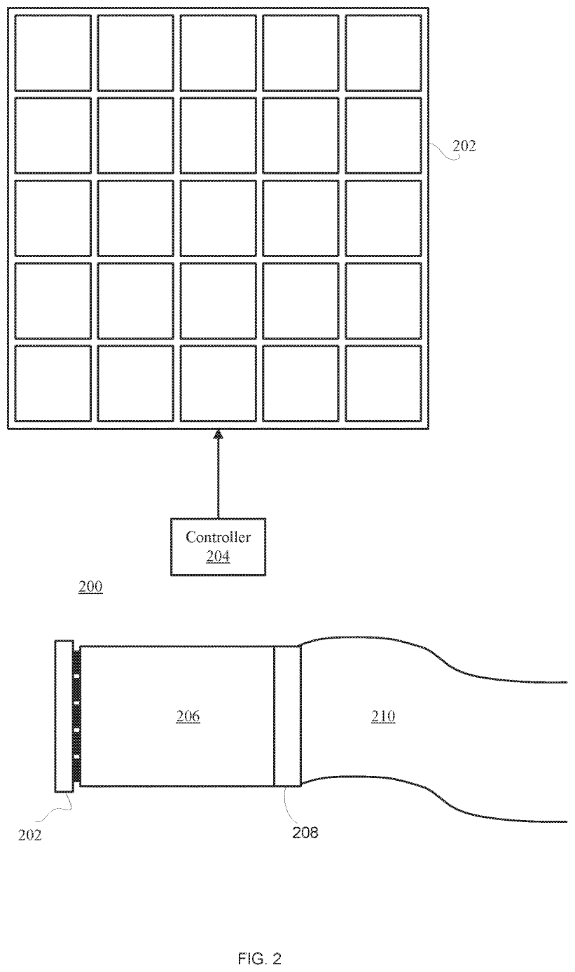

FIG. 2 is an example of an illumination source (200) which can be used as a component in optical metrology that enables precise sample illumination with customizable wavelength ranges and intensities. The LED Matrix (202) is a part of the illumination source (200), consisting of twenty-five LEDs organized into twelve LED Sets, each corresponding to specific Wavelength Ranges. This arrangement allows for independent control and intensity adjustment of each LED, facilitating tailored illumination for metrological applications.

The LED Matrix (202) serves as the core of the Illumination source (200), with its twenty-five light-emitting diodes grouped into twelve LED Sets. Each set is associated with a peak wavelength range, identified by the Wavelength Ranges, enabling the selection of specific wavelengths for different metrological tasks. The ability to operate each LED independently (or at least each set independently) allows for the customization of the illumination pattern, which is necessary for achieving the desired contrast and resolution on the sample's surface for precise measurements. The intensity of each LED is adjustable, providing control over the illumination conditions.

A System Controller (204) is communication with the Illumination source (200) to manage the activation and modulation of the LEDs. It can activate any combination of LEDs, allowing for a range of illumination scenarios. The controller can execute continuous or pulsed lighting sequences, tailored to the measurement strategy. It also follows predefined metrology recipes, ensuring repeatability and consistency in measurements. The controller's capability to select from various illumination combinations, including red, infrared, and blue light, enables the system to adapt to different metrological challenges. By controlling the matrix in accordance with these recipes, the system can illuminate the sample with optimal light conditions for each measurement cycle, enhancing the reliability and accuracy of the metrological process.

The LED Matrix (202) serves as the core of the illumination source for optical metrology. It consists of twenty-five light emitting diodes arranged into twelve sets, each corresponding to specific peak wavelength ranges. The first and second sets emit within the 400-500 nanometer range, while subsequent sets cover increasing wavelength ranges up to 1000 nanometers, extending from the visible spectrum into the infrared.

Each LED within the matrix can be independently controlled, allowing for the selection of individual LEDs or sets for activation. This feature enables the customization of the illumination pattern to match the requirements of the metrology task, whether it requires continuous or pulsed light, a single wavelength, or a combination. The intensity of each LED is adjustable, providing the means to fine-tune the illumination power for the sample being examined.

A system controller (204) interfaces with the LED Matrix, executing metrology recipes. It selects the appropriate LED combinations and controls their operation, whether continuous for steady-state measurements or pulsed for time-resolved analysis. This adaptability is key to adjusting the metrology system to various samples and measurement conditions, ensuring precise data acquisition.

The System Controller (204) is a component in the optical metrology illumination source that enables precise control over the LED Matrix (202). It manages the individual LED Sets and their Wavelength Ranges to achieve specific lighting conditions necessary for sample analysis.

The System Controller (204) is tasked with the operation of the LED Matrix (202), which includes the ability to independently manage each LED's intensity. This functionality allows for the customization of the illumination profile, enabling the selection of specific wavelengths for targeted sample analysis. The controller is capable of activating any combination of LEDs within the matrix, which is essential when different metrology recipes are required. This feature allows for the rapid switching between LED combinations without significant impact on throughput.

According to an embodiment, some of the LEDs comply with at least one of the following requirements:
1. Rise to full intensity within 100 μs.
2. Drop to 10⁻⁵ of their full intensity within after turn-off operation.

An example of properties of the LEDs of the 12 sets is illustrated in table 1.

TABLE 1

| | | | | Radiance for Entire |
|---|---|---|---|---|
| | | | Reference | set, Calibrated |
| | Peak | | LED | Nominal Current* |
| Set | Wavelength Range [nm] | LED Count | Current [mA] | $( \frac{mW}{{mm}^{2} sr} )$ |
| 1 | 400-405 | 1 | 500 | |
| 2 | 450-455 | 1 | 350 | 22 |
| 3 | 525-530 | 1 | 350 | 5.1 |
| 4 | 670-680 | 1 | 350 | 10.4 |
| 5 | 700-705 | 2 | 350 | 11.5 |
| 6 | 725-740 | 2 | 350 | 10.7 |
| 7 | 785-790 | 2 | 700 | 10.7 |
| 8 | 825-830 | 2 | 700 | 18 |
| 9 | 860-870 | 2 | 350 | 16.4 |
| 10 | 905-910 | 2 | 700 | 14.5 |
| 11 | 940-950 | 3 | 700 | 9.1 |
| 12 | 985-990 | 6 | 700 | 20.7 |
| Total | | 25 | | |

According to an embodiment the matrix operated in any one or more manners:
a. Operation of one or more sets of LEDs.
b. Operation of one or more LEDs of one or more sets of LEDs.
c. Continuous operation of one or more LEDs.
d. Non-continuous operation of one or more LEDs.
e. Continuous operation of one or more sets of LEDs.
f. Non-continuous operation of one or more sets of LEDs.

Additionally, the controller is configured to support both continuous and non-continuous illumination modes, providing flexibility in the temporal domain of sample exposure. It can also execute complex illumination strategies, such as varying the LED combinations during different illumination pulses, which is vital for optimizing the quality of the images captured during the metrology process and ensuring reliable feature detection.

The System Controller (204) serves as the command center for the LED Matrix (202), dictating the operational modes and intensity levels of the LEDs. This enables the Illumination source (200) to deliver tailored lighting conditions for precise optical measurements.

According to an embodiment, the matrix (202) is optically coupled to light coupling and homogenizing optics (206) such as an adaptor that includes a homogenizer and ends with a fiber coupler interface (208) that interfaces with an optical fiber or a fiber bundle (210).

An example of a fiber bundle is fiber bundle 945-00760-00, or 945-01468. Both with an active diameter of 4 mm. Other diameters may be provided.

The illumination configuration may change within an evaluation iteration or during a testing of the matrix.

A testing sequence may include:
1. Continuous 800 ms operation of IR LEDs.
2. 11 sec pulsed operation of either one of the red sets and/or the infrared sets.
   i. Pulse duration 4-30 msec
   ii. Consecutive pulses, with minimum of 10 ms off time between pulses.
   iii. Groups of up to 4 such pulses are separated by minimum of 200 ms off time between them.
   iv. 8 sec off time between the sequence described in 1, 2 and the next one.

Table 1 illustrates examples of different illumination configurations of the 12 sets of LEDs:

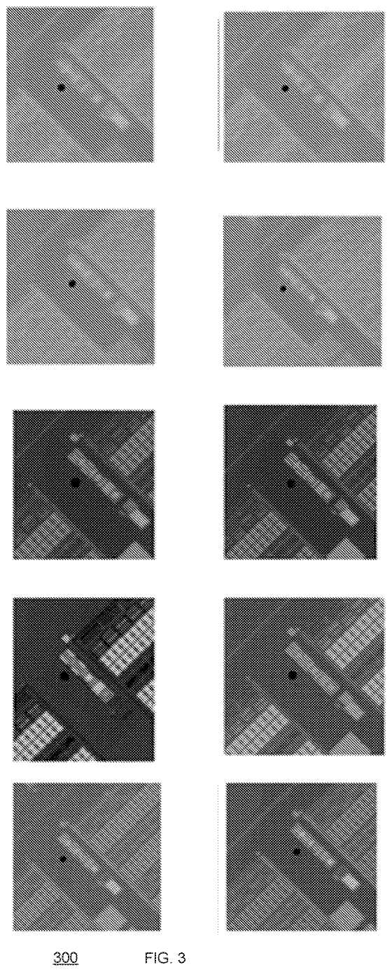

FIG. 3 illustrate an example of images collectively denoted 300 of a sample obtained under different illumination conditions.

In the following detailed description, numerous specific details are set forth to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method.

Any reference in the specification to a system should be applied mutatis mutandis to a method that may be executed by the system.

Any values (for example time values, dimensions, signal values, frequencies, standards) are merely non-limiting examples.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various connections carrying subsets of these signals. Therefore, many options exist for transferring signals.

Although specific conductivity types or polarity of potentials have been described in the examples, it will be appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein may be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above-described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also, for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. An illumination source for use in optical metrology, the illumination source comprises: a matrix that comprises twenty-five light emitting diodes (LEDs) that are arranged in twelve different sets of LEDs associated with twelve peak wavelength ranges, wherein (i) a first set and a second set have their peak wavelength range within the 400 till 500 nanometer range, (ii) a third set has its peak wavelength range within the 500 till 600 nanometer range, (iii) a fourth set has its peak wavelength range within the 600 till 700 nanometer range, (iv) wherein a fifth set, a sixth and a seventh set have their peak wavelength range within the 700 till 800 nanometer range, (v) an eighth set and a ninth set have their peak wavelength range within the 800 till 900 nanometer range, (vi) a tenth set, an eleventh set and a twelfth set have their peak wavelength range within the 900 till 1000 nanometer range.

2. The illumination source according to claim 1, wherein the first set has its peak wavelength range within the 400-405 nanometer sub-range, the second set has its peak wavelength range within the 450-455 nanometer sub-range, the third set has its peak wavelength range within the 525-530 nanometer sub-range, the fourth set has its peak wavelength range within the 670-680 nanometer sub-range, the fifth set has its peak wavelength range within the 700-705 nanometer sub-range, and the sixth set has its peak wavelength range within the 725-750 nanometer sub-range.

3. The illumination source according to claim 1, wherein the seventh set has its peak wavelength range within the 785-790 nanometer sub-range, the eighth set has its peak wavelength range within the 835-830 nanometer sub-range, the ninth set has its peak wavelength range within the 860-870 nanometer sub-range, the tenth set has its peak wavelength range within the 905-910 nanometer sub-range, the eleventh set has its peak wavelength range within the 940-950 nanometer sub-range, and the twelfth set has its peak wavelength range within the 985-990 nanometer sub-range.

4. The illumination source according to claim 1, wherein each set of the third till eleventh sets consists of more LEDs than the first till fourth sets, and the twelfth set has a highest number of LEDs of any of the sets.

5. The illumination source according to claim 1, wherein each set of the first till fourth sets consists of a single LED, each set of the fifth till tenth sets consist of a pair of LEDs, the eleventh set consists of three LEDs, and the twelfth set consists of six LEDs.

6. The illumination source according to claim 1, wherein each LED of any of the set is controlled independently from any other LED of the matrix.

7. The illumination source according to claim 1, wherein set is controlled independently from any other set of the matrix.

8. The illumination source according to claim 1, wherein each LED of the matrix has a controllable intensity.

9. The illumination source according to claim 1, further comprising a controller.

10. The illumination source according to claim 9, wherein the controller is configured to selectively activate any combination of any LEDs of the matrix.

11. The illumination source according to claim 9, wherein the controller is configured to select out of first plurality of red light illumination combinations, out of a second plurality of infrared illumination combinations and out of a third plurality of blue illumination combinations.

12. The illumination source according to claim 9, wherein the controller is configured to control at least one of the sets to continuously illuminate a sample.

13. The illumination source according to claim 9, wherein the controller is configured to control at least one of the sets to non-continuously illuminate a sample.

14. The illumination source according to claim 9, wherein the controller is configured to control the matrix based on a metrology recipe.

15. The illumination source according to claim 9, wherein the controller is configured to control the matrix to illuminate a sample with different combinations of LEDs during different illumination pulses.

16. The illumination source according to claim 1, wherein the matrix comprises more that twenty-five LEDs.

17. A method for illuminating a sample, the method comprises: illuminating a sample with radiation using an illumination source that comprises a matrix that comprises twenty-five light emitting diodes (LEDs) that are arranged in twelve different sets of LEDs associated with twelve peak wavelength ranges, wherein (i) a first set and a second set have their peak wavelength range within the 400 till 500 nanometer range, (ii) a third set has its peak wavelength range within the 500 till 600 nanometer range, (iii) a fourth set has its peak wavelength range within the 600 till 700 nanometer range, (iv) wherein a fifth set, a sixth and a seventh set have their peak wavelength range within the 700 till 800 nanometer range, (v) an eighth set and a ninth set have their peak wavelength range within the 800 till 900 nanometer range, (vi) a tenth set, an eleventh set and a twelfth set have their peak wavelength range within the 900 till 1000 nanometer range.

18. The method of claim 17, wherein the first set has its peak wavelength range within the 400-405 nanometer sub-range, the second set has its peak wavelength range within the 450-455 nanometer sub-range, the third set has its peak wavelength range within the 525-530 nanometer sub-range, the fourth set has its peak wavelength range within the 670-680 nanometer sub-range, the fifth set has its peak wavelength range within the 700-705 nanometer sub-range, and the sixth set has its peak wavelength range within the 725-750 nanometer sub-range.

19. The method of claim 17, wherein the seventh set has its peak wavelength range within the 785-790 nanometer sub-range, the eighth set has its peak wavelength range within the 835-830 nanometer sub-range, the ninth set has its peak wavelength range within the 860-870 nanometer sub-range, the tenth set has its peak wavelength range within the 905-910 nanometer sub-range, the eleventh set has its peak wavelength range within the 940-950 nanometer sub-range, and the twelfth set has its peak wavelength range within the 985-990 nanometer sub-range.

20. The method of claim 17, wherein each set of the third till eleventh sets consists of more LEDs than the first till fourth sets, and the twelfth set has a highest number of LEDs of any of the sets.

21. The method of claim 17, wherein each set of the first till fourth sets consists of a single LED, each set of the fifth till tenth sets consist of a pair of LEDs, the eleventh set consists of three LEDs, and the twelfth set consists of six LEDs.
